(19) United States
(12) Patent Application Publication
(10) Pub. No.: US 2014/0076402 A1
(43) Pub. Date: Mar. 20, 2014

(54) CONTROLLED DEPOSITION OF PHOTOVOLTAIC THIN FILMS USING INTERFACIAL WETTING LAYERS

(71) Applicants: Jason D. Myers, Alexandria, VA (US); Jesse A. Frantz, Landover, MD (US); Robel Y. Bekele, Washington, DC (US); Jasbinder S. Sanghera, Ashburn, VA (US); Ishwar D. Aggarwal, Charlotte, NC (US)

(72) Inventors: Jason D. Myers, Alexandria, VA (US); Jesse A. Frantz, Landover, MD (US); Robel Y. Bekele, Washington, DC (US); Jasbinder S. Sanghera, Ashburn, VA (US); Ishwar D. Aggarwal, Charlotte, NC (US)

(21) Appl. No.: 14/026,130

(22) Filed: Sep. 13, 2013

Related U.S. Application Data
(60) Provisional application No. 61/700,901, filed on Sep. 14, 2012.

(51) Int. Cl. H01L 31/032; H01L 31/18

(52) U.S. Cl. CPC H01L 31/0322; H01L 31/18
USPC 136/262; 438/95; 136/252; 136/264

(57) ABSTRACT

A method for forming a photovoltaic device by depositing at least one wetting layer onto a substrate where the wetting layer is ≦100 nm and sputtering a photovoltaic material onto the wetting layer where the wetting layer interacts with the photovoltaic material. Also disclosed is the related photovoltaic device made by this method. The wetting layer may comprise any combination of In₂Se₃, CuSe₂, Cu₂Se, Ga₂Se₃, In₂S₃, CuS₂, Cu₂S, Ga₂S₃, CuInSe₂, CuGaSe₂, InₓGa₂₋ₓSe₃ where 0≦x≦2, CuInS₂, CuGaS₂, InₓGa₂₋ₓS₃ where 0≦x≦2, In₂Se₃₋ₓSₓ where 0≦x≦3, CuSe₂₋ₓSₓ where 0≦x≦2, Cu₂Se₁₋ₓSₓ, (0≦x≦1), Ga₂Se₃₋ₓSₓ where 0≦x≦3, and InₓGa₂₋ₓS_{3-y}S_{y} where 0≦x≦2, 0≦y≦3. The photovoltaic material may be a CIGS (copper indium gallium diselenide) material or a variation of a CIGS material where a CIGS component is replaced or supplemented with any combination of sulfur, tellurium, aluminum, and silver.

### PRIORITY CLAIM

This Application claims priority from U.S. Provisional Application No. 61/700,901 filed on Sep. 14, 2012 by Jason D. Myers et al., entitled “Controlled Growth of Copper Indium Gallium Diselenide Thin Films Using Interfacial Wetting Layers.” The entire contents of the provisional application and all references cited throughout this application and the provisional application are incorporated herein by reference.

### BACKGROUND OF THE INVENTION

1. Field of the Invention

The present invention relates generally to photovoltaic devices and, more specifically, to deposition of photovoltaic material on an interfacial wetting layer.

2. Description of the Prior Art

Cu(In₋ₓGaₓ)Se₂, (0≦x≦1) (CIGS) has been established as a promising material for thin film photovoltaics, with record laboratory power conversion efficiencies of ˜20%. (I. Repins et al., “19.9%-efficient ZnO/CdS/CuInGaSe2 solar cell with 81.2% fill factor,” Progress in Photovoltaics: Research and Applications, 16, 235-239 (2008)). Thin films of CIGS are typically deposited using one of several methods. Thermal co-evaporation has demonstrated the highest efficiencies in the laboratory, but sputtering precursors followed by selenization has found adoption in industry. (N. G. Dhere, “Toward GW/year of CIGS production within the next decade,” Solar Energy Materials and Solar Cells, 91, 1376-1382 (2007)). It is also possible to directly sputter the quaternary compound without post-selenization. (J. A. Frantz et al., “Cu(In,Ga)Se₂ thin films and devices sputtered from a single target without additional selenization,” Thin Solid Films, 519, 7763-7765 (2011)).

Extensive research has been performed to determine the optimum growth conditions of CIGS that result in a desirable film morphology. The highest efficiency laboratory devices utilize the so-called “three-stage” process where three different compositions are co-evaporated in succession on top of a molybdenum electrical contact. Upon annealing a dense, large-grained structure emerges in the completed film. While this is practical at the laboratory scale for co-evaporation, sputtering, particularly single-target quaternary sputtering, does not natively form this desirable microstructure without extensive post processing and annealing.

### BRIEF SUMMARY OF THE INVENTION

The present invention pertains to the use of thin interfacial films to wet and improve the film quality of subsequently deposited photovoltaic thin films, such as Cu(In₁₋ₓGaₓ)Se₂, (0≦x−1) (CIGS). The present invention provides a method for forming a photovoltaic device by depositing at least one wetting layer onto a substrate where the wetting layer is <100 nm and sputtering a photovoltaic material onto the wetting layer where the wetting layer interacts with the photovoltaic material. Also disclosed is the related photovoltaic device made by this method.

The present system has advantages over other CIGS thin films and methods of making the CIGS thin films. The present invention can eliminate the need for post-deposition selenization and/or annealing because the desired morphology can be influenced by the interfacial layer. As a result of the elimination of post-deposition selenization and/or annealing, the present invention makes it possible to deposit on substrates that cannot tolerate high temperatures, such as plastics. Also, the present invention can make lower-cost deposition methods, such as quaternary sputtering, competitive with state-of-the-art co-evaporation. Moreover, the wetting layer of the present invention can be deposited on flexible or rigid substrates selected from several materials including plastics, metals, ceramics, and glasses. Additionally, the present invention enables deposition of CIGS and its variations including addition/substitution of S, Te, Al, Ag, and others. Furthermore, the proposed invention could enable higher efficiencies than those obtained by evaporation techniques, i.e. >21%.

These and other features and advantages of the invention, as well as the invention itself, will become better understood by reference to the following detailed description, appended claims, and accompanying drawings.

### BRIEF DESCRIPTION OF THE DRAWINGS

FIG. 1 is an SEM image of a bare molybdenum thin film on soda lime glass.

FIG. 2 shows SEM images of the initial growth of CIGS on molybdenum. FIG. 2(a) is a top-down view, and FIG. 2(b) is a cross-section view.

FIG. 3 shows SEM images of In₂Se₃ on molybdenum. FIG. 2(a) is a top-down view, and FIG. 2(b) is a cross-section view.

FIG. 4 shows SEM images of (a) CIGS on bare molybdenum and (b) CIGS on molybdenum with an In₂Se₃ wetting layer.

FIG. 5 shows cross-section SEM images of (a) CIGS on bare molybdenum and (b) CIGS on molybdenum with an In₂Se₃ wetting layer.

### DETAILED DESCRIPTION OF THE INVENTION

The present invention provides a method for inducing a desirable morphology in photovoltaic thin films by first depositing an interfacial wetting layer, such as In₂Se₃, before deposition of a photovoltaic material, such as a CIGS material. Without a wetting layer, CIGS exhibits a strong preference for island growth on molybdenum, the industry standard back electrical contact. (T. Schlenker et al., “Initial growth behavior of Cu(In,Ga)Se₂ on molybdenum substrates,” Journal of Crystal Growth, 259, 47-51 (2003)). This island growth leads to smaller grains and poor electrical transport and optical performance near the Mo interface, compromising the performance of the PV device. However, with a wetting layer that has a more favorable interaction energy with CIGS, island growth can be suppressed to allow for larger grains and a more preferable morphology to grow without additional processing and expense, leading to superior device performance.

Several materials may be used for the wetting layer. In₂Se₃, CuSe₂, Cu₂Se, Ga₂Se₃, or any combination thereof. Ternary compounds such as CuInSe₂, CuGaSe₂, InₓGa₂₋ₓSe₃, (0≦x≦2), or any combination thereof can be used. Multiple layers, such as a stack of In₂Se₃, Ga₂Se₃, CuSe₂, Cu₂Se or any combination thereof can be used. Sulfide analogues, such as In₂S₃, Ga₂S₃, CuS₂, Cu₂S or any combination thereof can be used along with their ternary compounds, such as CuInS₂, CuGaS₂, InₓGa₂₋ₓS₃, (0≦x≦2), or any combination thereof. Sulfide-selenide compounds, such as In₂Se₃₋ₓSₓ, (0≦x≦3), CuSe₂₋ₓSₓ, (0≦x≦2), Cu₂Se₁₋ₓSₓ, (0≦x≦1) and Ga₂Se₃₋ₓSₓ, (0≦x≦3) and related compounds, including InₓGa₂₋ₓS_{3-y}S_{y}, (0≦x≦2, 0≦y≦3) and other similar compounds may also be used along with any combination thereof. Other materials that favorably interact with the photovoltaic material may also be used.

The composition of the interfacial layer can be varied to modify its interaction with both CIGS and molybdenum (or another electrode material). This could result in, for example, control of the subsequent CIGS morphology without changes in deposition conditions. Additionally, multiple materials could be used to form a stack of interfacial layers, or a single (or multiple) layer structure consisting of a composite material, such as a ternary compound (i.e. InxGa2-xSe3, (0≦x≦2)). The present invention is also compatible with the sulfide-selenide analogue of CIGS, Cu(In₁₋ₓGaₓ)S_{2-y}Se_{y}, (0≦x≦1, 0≦y≦2).

The wetting layer should be less than or equal to 100 nm. In a preferred embodiment, the wetting layer was between 10 and 20 nm. The thickness of the photovoltaic material, e.g. CIGS, is typically between 1-2 μm.

In one embodiment of the invention, the photovoltaic material is deposited by sputtering. Unlike other sputtering techniques, the present invention does not require further selenization treatment after sputtering.

### EXAMPLE

A sputtering target of In₂Se₃ can be fabricated in-house by material synthesis and machining or commercially purchased. Deposition was carried out onto a molybdenum-coated soda lime glass substrate, where the molybdenum served as the bottom electrode (anode) of the photovoltaic device. In₂Se₃ was deposited onto the substrate using RF magnetron sputtering in a sputter-up geometry in an Ar atmosphere at a pressure of 1-5 mT with an energy density on the order of 0.5-2 W/cm² with the substrate held at room temperature. The nominal thickness of the deposited In₂Se₃ layer was 10-20 nm. The substrate was rotated at ˜10 rpm during deposition.

Subsequently, quaternary CIGS was sputtered onto the In₂Se₃ layer from a single target in a similar geometry with an energy density of ˜4 W/cm² and a chamber pressure of 1-5 mT in an Ar atmosphere. The total CIGS thickness was 1-2 μm. The substrate temperature was approximately 550° C.

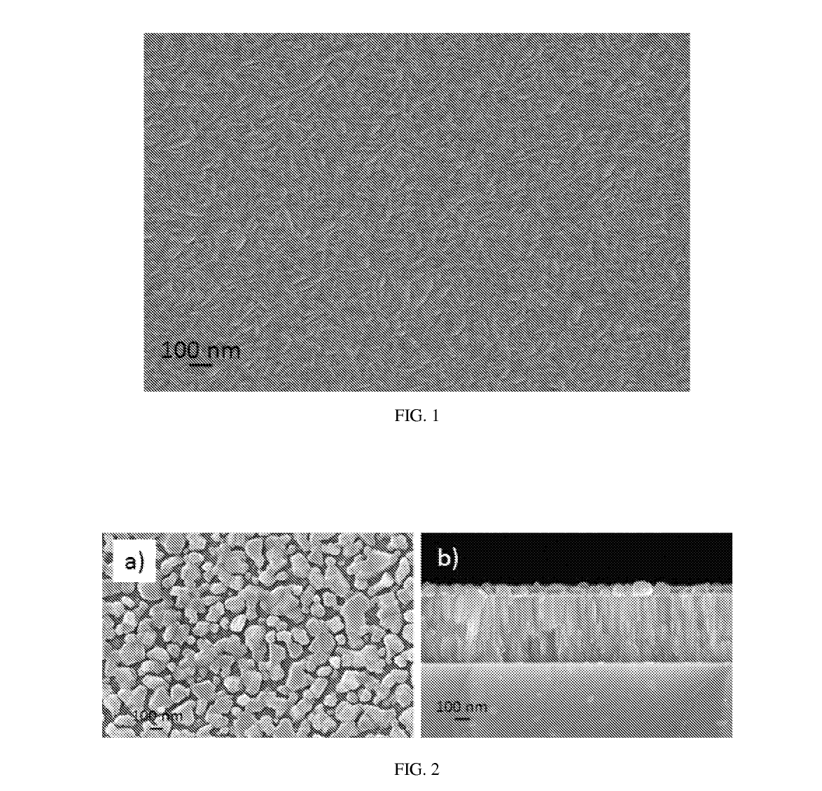

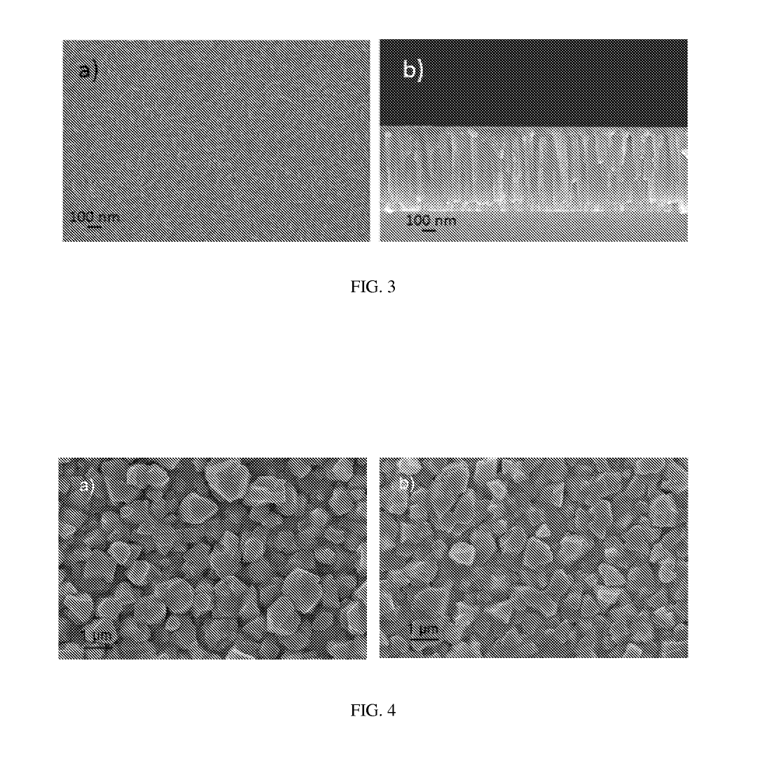

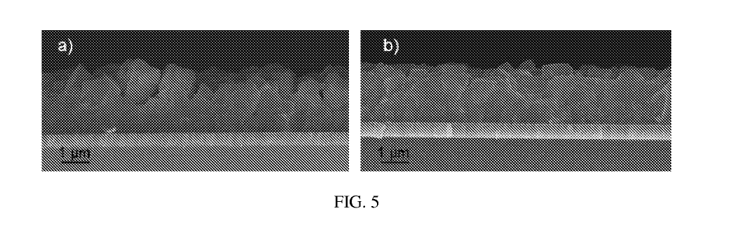

FIG. 1 shows a bare molybdenum surface. FIG. 2 demonstrates the morphology of a thin layer (˜70 nm thick) of CIGS nucleating directly on a molybdenum surface. There is strong island growth. FIG. 3 shows a thin layer of In₂Se₃ on molybdenum, with complete wetting behavior demonstrated. Finally, FIG. 4 shows the difference in morphology that results in a 1-2 μm thick layer of CIGS deposited with and without an In₂Se₃ wetting layer. FIG. 5 shows cross-section SEM images of (a) CIGS on bare molybdenum and (b) CIGS on molybdenum with an In₂Se₃ wetting layer.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A method for forming a photovoltaic device, comprising:
depositing at least one wetting layer onto a substrate wherein the wetting layer is less than or equal to 100 nm; and
depositing a photovoltaic material onto the wetting layer wherein the wetting layer interacts with the photovoltaic material.

2. The method of claim 1, wherein the wetting layer comprises In₂Se₃, CuSe₂, Cu₂Se, Ga₂Se₃, In₂S₃, CuS₂, Cu₂S Ga₂S₃, CuInSe₂, CuGaSe₂, InₓGa₂₋ₓSe₃ where 0≦x≦2, CuInS₂, CuGaS₂, InₓGa₂₋ₓS₃ where 0≦x≦2, In₂Se₃₋ₓSₓ where 0≦x≦3, CuSe₂₋ₓSₓ where 0≦x≦2, Cu₂Se₁₋ₓSₓ, (0≦x≦1), Ga₂Se₃₋ₓSₓ where 0≦x≦3, InₓGa₂₋ₓS_{3-y}S_{y} where 0≦x≦2, 0≦y≦3, or any combination thereof.

3. The method of claim 1, wherein the substrate comprises molybdenum.

4. The method of claim 1, wherein the substrate comprises plastic, metal, ceramic, glass, or any combination thereof.

5. The method of claim 1, wherein the photovoltaic material comprises a copper indium gallium diselenide (CIGS) material.

6. The method of claim 1, wherein the photovoltaic material comprises a variation of a copper indium gallium diselenide (CIGS) material wherein a CIGS component is replaced or supplemented with sulfur, tellurium, aluminum, silver, or any combination thereof.

7. The method of claim 1, wherein the photovoltaic material is deposited by sputtering.

8. The method of claim 1, wherein the photovoltaic device does not require selenization after deposition of the photovoltaic material.

9. A photovoltaic device made by the method comprising:
depositing at least one wetting layer onto a substrate wherein the wetting layer is less than or equal to 100 nm; and
depositing a photovoltaic material onto the wetting layer wherein the wetting layer interacts with the photovoltaic material.

10. The device of claim 9, wherein the wetting layer comprises In₂Se₃, CuSe₂, Cu₂Se, Ga₂Se₃, In₂S₃, CuS₂, Cu₂S, Ga₂S₃, CuInSe₂, CuGaSe₂, InₓGa₂₋ₓSe₃ where 0≦x≦2, CuInS₂, CuGaS₂, InₓGa₂₋ₓS₃ where 0≦x≦2, In₂Se₃₋ₓSₓ where 0≦x≦3, CuSe₂₋ₓSₓ where 0≦x≦2, Cu₂Se₁₋ₓSₓ, (0≦x≦1), Ga₂Se₃₋ₓSₓ where 0≦x≦3, InₓGa₂₋ₓS_{3-y}S_{y} where 0≦x≦2, 0≦y≦3, or any combination thereof.

11. The device of claim 9, wherein the substrate comprises molybdenum.

12. The device of claim 9, wherein the substrate comprises plastic, metal, ceramic, glass, or any combination thereof.

13. The device of claim 9, wherein the photovoltaic material comprises a copper indium gallium diselenide (CIGS) material.

14. The device of claim 9, wherein the photovoltaic material comprises a variation of a copper indium gallium diselenide (CIGS) material wherein a CIGS component is replaced or supplemented with sulfur, tellurium, aluminum, silver, or any combination thereof.

15. The device of claim 9, wherein the photovoltaic material is deposited by sputtering.

16. The device of claim 9, wherein the photovoltaic device does not require selenization after deposition of the photovoltaic material.
